(19) United States
(12) Patent Application Publication
(10) Pub. No.: US 2023/0386844 A1
(43) Pub. Date: Nov. 30, 2023

(54) METHOD OF MANUFACTURING SEMICONDUCTOR DEVICE AND SEMICONDUCTOR DEVICE

(71) Applicant: SUMITOMO HEAVY INDUSTRIES, LTD., Tokyo (JP)

(72) Inventors: Suguru YACHI, Yokosuka-shi (JP); Takeshi AIBA, Yokosuka-shi (JP)

(21) Appl. No.: 18/449,705

(22) Filed: Aug. 15, 2023

Related U.S. Application Data
(63) Continuation of application No. PCT/JP2022/000789, filed on Jan. 12, 2022.

(30) Foreign Application Priority Data
Feb. 17, 2021 (JP) 2021-023302

(51) Int. Cl. H01L 21/22; H01L 29/32; H01L 21/268

(52) U.S. Cl. CPC H01L 21/221; H01L 29/32; H01L 21/268

(57) ABSTRACT

A method of manufacturing a semiconductor device includes: performing laser annealing on a silicon substrate in which point defects are generated due to ion implantation of a dopant to activate the dopant; and growing the point defects into {311} defects or dislocation loops and using the {311} defects or the dislocation loops as lifetime killers.

### CROSS-REFERENCE TO RELATED APPLICATIONS

This is a bypass continuation of International PCT Application No. PCT/JP2022/000789, filed on Jan. 12, 2022, which claims priority to Japanese Patent Application No. 2021-023302, filed on Feb. 17, 2021, which are incorporated by reference herein in their entirety.

### BACKGROUND

### Technical Field

Certain embodiments of the present invention relate to a method of manufacturing a semiconductor device and a semiconductor device.

### Description of Related Art

A power semiconductor device using the p-n junction of silicon, for example, an insulated gate bipolar transistor (IGBT) is publicly known. In the IGBT, a tail current generated by carriers accumulated in a drift layer during turn-off causes an increase in switching loss. It is possible to reduce a switching loss by generating lifetime killers, such as defects, in a silicon layer and shortening the lifetime of the carriers. A technique for controlling a lifetime by implanting a light element, such as proton or helium, into a silicon layer to generate defects in the silicon layer is publicly known in the related art.

### SUMMARY

According to an embodiment of the present invention, there is provided a method of manufacturing a semiconductor device.

The method includes performing laser annealing on a silicon substrate in which point defects are generated due to ion implantation of a dopant to activate the dopant, and growing the point defects into defects or dislocation loops and using the {311} defects or the dislocation loops as lifetime killers.

According to another embodiment of the present invention, there is provided a semiconductor device including a first layer which is disposed in an outer layer portion of a silicon substrate and into which a first conductive type dopant is implanted, a second layer that is disposed in a region of the silicon substrate shallower than the first layer and into which a second conductive type dopant is implanted, and lifetime killers that are formed of {311} defects or dislocation loops formed in at least one of the first layer and the second layer.

### BRIEF DESCRIPTION OF THE DRAWINGS

FIG. 1 is a schematic diagram showing a laser annealing apparatus that is used in a method of manufacturing a semiconductor device according to an embodiment.

FIG. 2 is a flowchart showing a procedure of the method of manufacturing a semiconductor device according to the embodiment.

FIGS. 3A and 3B are cross-sectional views of a semiconductor device in manufacturing steps, and FIG. 3C is a cross-sectional view of the semiconductor device after the manufacturing steps end.

FIG. 4 is a schematic diagram illustrating the movement of a beam spot during laser annealing.

A right diagram in FIG. 5 is a graph showing an example of a distribution of a dopant concentration in a depth direction, and a left diagram in FIG. 5 is a schematic diagram showing distributions of dislocation loops in a depth direction of a silicon substrate.

FIGS. 6A and 6B are cross-section TEM images of the silicon substrate before and after laser annealing, respectively.

FIGS. 7A and 7B are cross-section TEM images of a silicon substrate in a case where annealing is performed with pulse energy densities of 90% and 97% of a minimum pulse energy density at which the surface of the silicon substrate is melted due to the incidence of a pulsed laser beam (hereinafter, referred to as a melting threshold), respectively.

FIGS. 8A and 8B are cross-section TEM images obtained after the laser annealing of samples that are prepared under conditions in which doses of phosphorus are set to 5×10¹⁴ cm⁻² and 1×10¹³ cm⁻², respectively.

FIGS. 9A and 9B are graphs showing a relationship between a pulse energy density and an activation rate.

### DETAILED DESCRIPTION

In a method of generating lifetime killers in the related art, a step of implanting a light element and a step of performing annealing should be added to a step of manufacturing the semiconductor device. It is desirable to provide a method of manufacturing a semiconductor device that can generate lifetime killers without increasing the number of manufacturing steps, and a semiconductor device.

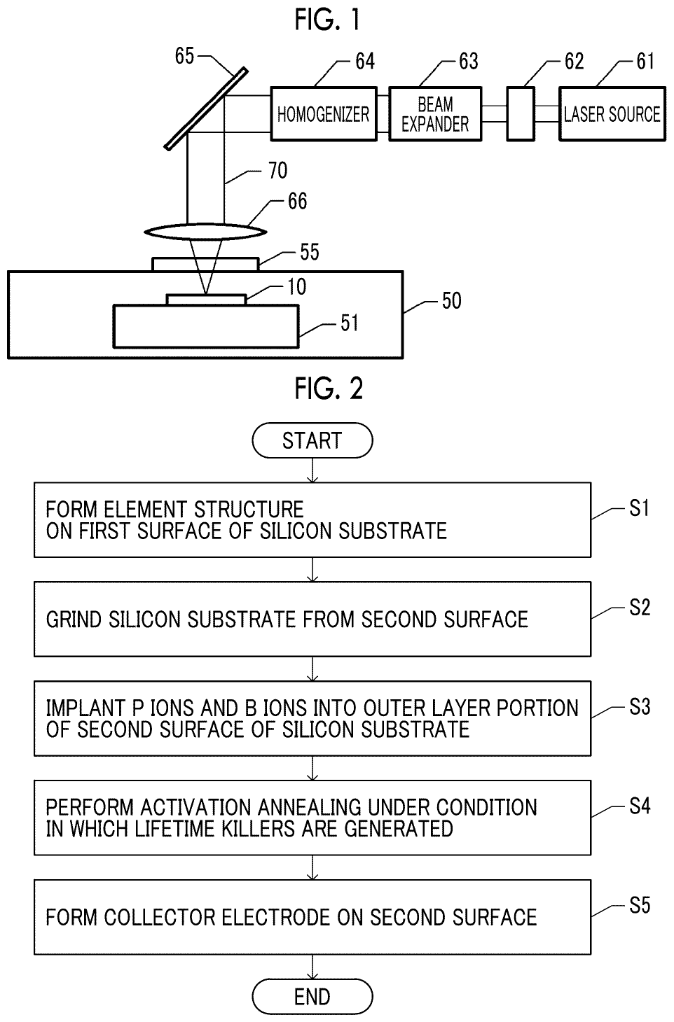

A method of manufacturing a semiconductor device and a semiconductor device according to embodiments of the present invention will be described with reference to FIGS. 1 to 9B.

FIG. 1 is a schematic diagram showing a laser annealing apparatus that is used in the method of manufacturing a semiconductor device according to the present embodiment. A silicon substrate 10 into which a dopant is ion-implanted is held on a movable stage 51 accommodated in a process chamber 50. A laser beam introduction window 55 is attached to a top panel of the process chamber 50.

A laser source 61 outputs a quasi-continuous wave (QCW) laser beam 70 having, for example, a wavelength of 808 nm. A laser source that outputs a laser beam in an infrared region having a wavelength of 800 nm or more and 950 nm or less may be used. For example, a laser diode is used as the laser source 61. Another laser oscillator, for example, a solid laser oscillator, such as an Nd:YAG laser, may be used as the laser source 61.

The laser beam 70 output from the laser source 61 passes through an attenuator 62, a beam expander 63, and a homogenizer 64 and is reflected downward by a reflective mirror 65. The laser beam 70, which is reflected downward, is introduced into the process chamber 50 via a condensing lens 66 and the laser beam introduction window 55. The laser beam introduced into the process chamber 50 is incident on the silicon substrate 10.

The beam expander 63 collimates the laser beam 70 and increases the diameter of the beam. The homogenizer 64 and the condensing lens 66 shape a beam spot on the surface of the silicon substrate 10 into a shape long in one direction, and homogenize light intensity distribution within the cross section of a beam. The movable stage 51 moves the silicon substrate 10 in two directions perpendicular to an optical axis of the condensing lens 66, so that the laser beam 70 can be caused to be incident on substantially the entire surface of the silicon substrate 10.

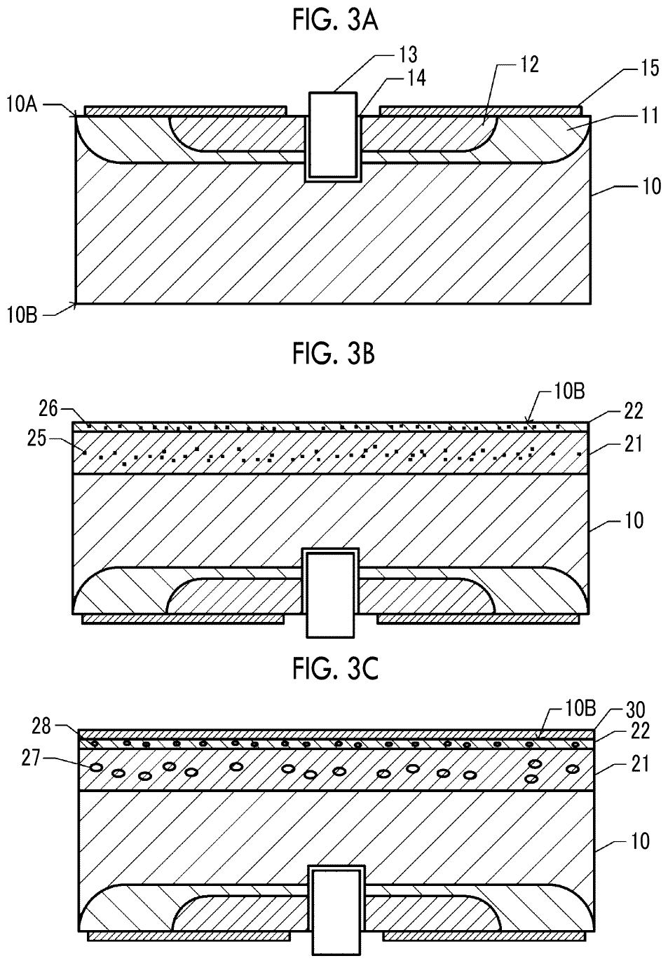

Next, the method of manufacturing a semiconductor device according to the present embodiment will be described with reference to FIGS. 2 to 4. In the present embodiment, an insulated gate bipolar transistor (IGBT) is manufactured as the semiconductor device.

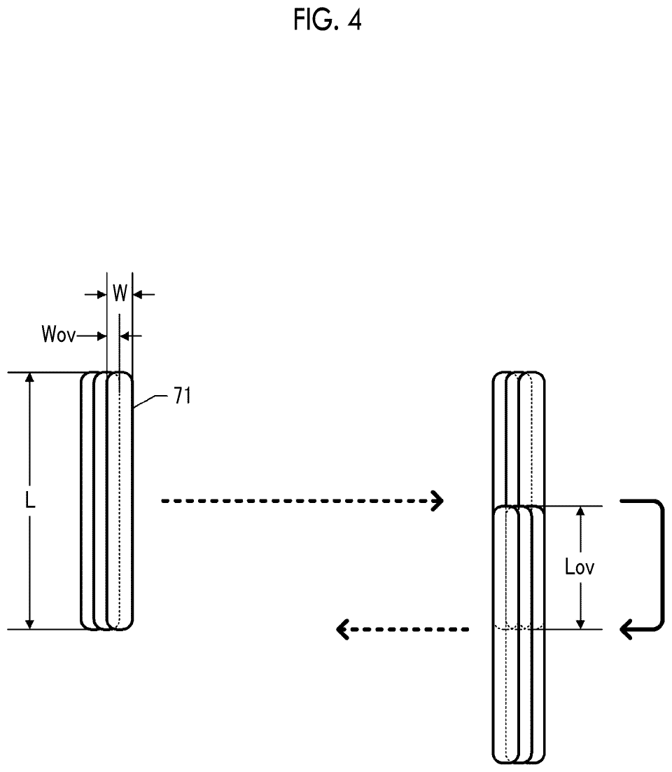

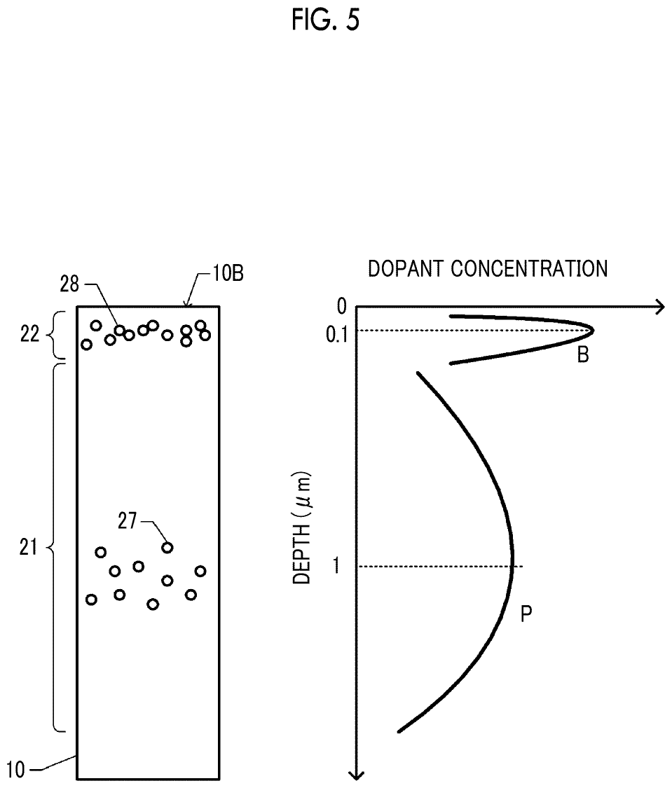

FIG. 2 is a flowchart showing a procedure of the method of manufacturing a semiconductor device according to the present embodiment. FIGS. 3A and 3B are cross-sectional views of a semiconductor device in manufacturing steps, and FIG. 3C is a cross-sectional view of the semiconductor device after the manufacturing steps end. FIG. 4 is a schematic diagram illustrating the movement of a beam spot during laser annealing.

First, an element structure shown in FIG. 3A is formed on a first surface 10A that is one surface of an n-type conductive silicon substrate 10 (Step S1). The element structure formed on the first surface 10A will be described below. A p-type base region 11, an n-type emitter region 12, a gate electrode 13, a gate insulating film 14, and an emitter electrode 15 are formed in an outer layer portion of the first surface 10A of the silicon substrate 10. This element structure can be formed using a publicly known semiconductor process. The on/off control of a current can be performed with a voltage between a gate and an emitter. For example, aluminum is used for the emitter electrode 15.

After the element structure is formed on the outer layer portion of the first surface 10A, the silicon substrate 10 is thinned by being ground from a second surface 10B thereof opposite to the first surface (Step S2). For example, the thickness of the silicon substrate 10 is reduced to a range of 50 μm to 200 μm.

After the silicon substrate 10 is ground, phosphorus (P) ions and boron (B) ions are implanted into the silicon substrate 10 from the second surface 10B of the silicon substrate 10 (Step S3). Accordingly, as shown in FIG. 3B, a first layer 21 into which phosphorus is implanted is formed, and a second layer 22 into which boron is implanted is formed in a region shallower than the first layer 21. In FIG. 3B, the cross-sectional view of the FIG. 3A is shown to be upside down. Due to ion implantation, a plurality of point defects 25 are generated in the first layer 21 and a plurality of point defects 26 are also generated in the second layer 22. The point defects 25 and 26 include vacancies or interstitial silicon atoms.

After ion implantation, a laser beam is caused to be incident on the second surface 10B of the silicon substrate 10 to perform activation annealing under a condition in which lifetime killers are generated (Step S4). For example, a pulsed laser beam having a wavelength of 600 nm to 1200 nm and a pulse width of 10 μs to 100 μs is used for this laser annealing. A continuous wave (CW) laser may be used. In a case where a continuous wave laser is used, the size of a beam spot and a scanning speed can be adjusted to control the incidence time of the laser beam.

P in the first layer 21 and B in the second layer 22 are activated due to this activation annealing. The second layer 22 functions as a collector layer of the IGBT. The first layer 21 may be referred to as a buffer layer. An n-type region of the silicon substrate 10 may be referred to as a drift layer. In the activation annealing, as shown in FIG. 3C, {311} defects grow from the point defects 25 and 26 and dislocation loops 27 and 28 are generated due to the {311} defects. After that, a collector electrode 30 is formed on a surface of the second layer 22 (Step S5).

The {311} defects are rod-shaped defects extending in a <110> direction on a {311} plane, and are generated since excessive interstitial silicon atoms generated due to ion implantation are precipitated in a very early stage of heat treatment. The {311} defects serve as a primary storage for the excessive interstitial silicon atoms.

In a case where heat treatment continues to be performed after the {311} defects are generated, the {311} defects are decomposed, so that interstitial silicon atoms are released. The dislocation loops 27 and 28 grow by absorbing the interstitial silicon atoms released due to the decomposition of the {311} defects. Each of the dislocation loops is a defect in which silicon atoms are clustered in the shape of a disk for one layer of atoms on a {111} plane, and looks like the shape of a ring or a coffee bean in a transmission electron microscope image (TEM image).

In general, additional laser annealing is performed to eliminate the dislocation loops. The wavelength of a pulsed laser beam used for the additional laser annealing is in, for example, a wavelength range of green light, and the pulse width of the pulsed laser beam is 1/10 or less of the pulse width of the pulsed laser beam used for the laser annealing of Step S4. Due to this additional laser annealing, the dislocation loops are substantially eliminated and an activation rate is increased. On the other hand, in the present embodiment, the dislocation loops are used as lifetime killers without being eliminated.

Next, a laser irradiation procedure in the activation annealing (Step S4) will be described with reference to FIG. 4. FIG. 4 is a schematic diagram showing an aspect of the movement of a beam spot 71 on the surface of the silicon substrate 10. The beam spot 71 has a shape long in one direction. A dimension of the beam spot 71 in a longitudinal direction is denoted by L, and a dimension of the beam spot 71 in a width direction perpendicular to the longitudinal direction is denoted by W. A pulsed laser beam is used in the activation annealing.

A procedure of moving the beam spot 71 in the width direction on the surface of the silicon substrate 10 and a procedure of shifting the beam spot 71 in the longitudinal direction are repeated to irradiate substantially the entire surface of the silicon substrate 10 with the laser beam. Actually, as shown in FIG. 1, the path of the laser beam 70 is fixed and the silicon substrate 10 is moved.

An overlap width of beam spots 71 of two adjacent shots on a time axis is denoted by Wov. An overlap length in a case where the beam spot 71 is shifted in the longitudinal direction is denoted by Lov. Wov/W is referred to as an overlap ratio in the width direction, and Lov/L is referred to as an overlap ratio in the longitudinal direction. For example, an overlap ratio in the width direction is set to 67% and an overlap ratio in the longitudinal direction is set to 50%.

Next, a relationship between a distribution of a dopant concentration and distributions of the dislocation loops 27 and 28 will be described with reference to FIG. 5. A right diagram in FIG. 5 is a graph showing an example of the distribution of a dopant concentration in a depth direction. A vertical axis represents a depth in the unit “μm”, and a horizontal axis represents dopant concentration. Phosphorus is implanted into a relative deep region and boron is implanted into a shallow region. For example, a depth at which a boron concentration has a maximum value is about 0.1 μm and a depth at which a phosphorus concentration has a maximum value is about 1 μm.

A left diagram in FIG. 5 is a schematic diagram showing distributions of the dislocation loops 27 and 28 in the depth direction of the silicon substrate 10. The dislocation loops 27 in the first layer 21 are generated near the depth at which a phosphorus concentration has a maximum value, and the dislocation loops 28 in the second layer 22 are generated near the depth at which a boron concentration has a maximum value. That is, the dislocation loops 27 and 28 are unevenly distributed in a region having a depth at which a dopant concentration is highest in the depth direction of the silicon substrate 10. For example, the dislocation loops are distributed such that a difference between the depth of a region in which a dopant concentration is highest and an average depth of the distributed dislocation loops is 3 times or less a standard deviation of the depths of the distributed dislocation loops. In a case where depths of ion implantation are changed, the depths of regions in which the dislocation loops 27 and 28 are generated can be changed.

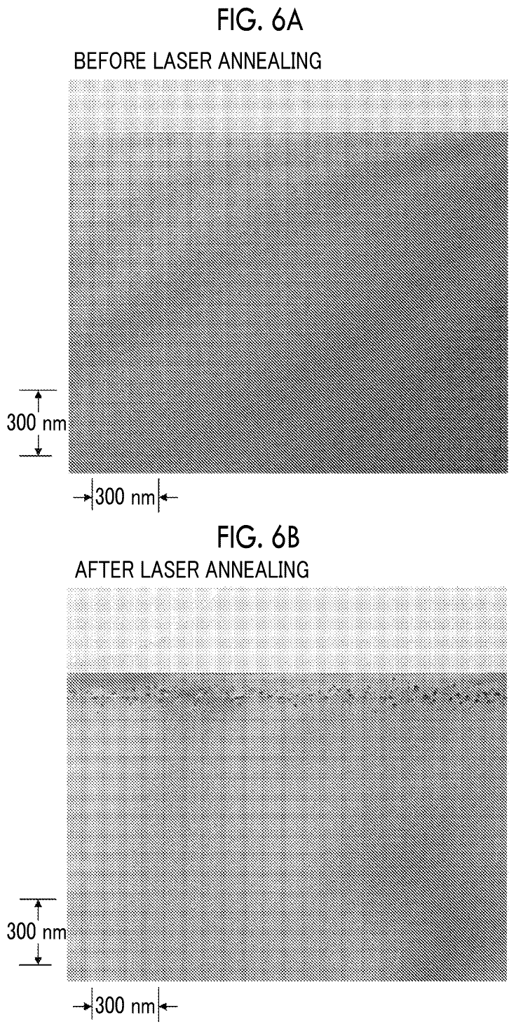

Next, an evaluation experiment for confirming the generation of dislocation loops caused by laser annealing will be described with reference to FIGS. 6A and 6B.

FIGS. 6A and 6B are cross-section TEM images of the silicon substrate before and after laser annealing, respectively. A sample is a silicon substrate into which boron ions are implanted under a condition in which a concentration reaches a peak at a depth of about 100 nm, respectively. A pulsed laser beam in an infrared region having a wavelength of 808 nm is used for the laser annealing.

Before the laser annealing, no defect is observed in the TEM image (FIG. 6A). However, point defects, such as vacancies and interstitial silicon atoms, are generated. It is found that many defects are generated in a depth range of 50 nm or more and 160 nm or less in the sample subjected to the laser annealing. These defects are dislocation loops. The depth of a region in which many dislocation loops are generated is substantially equal to a depth at which a boron concentration reaches a peak. In a case where laser annealing is performed under an appropriate condition as described above, many dislocation loops can be generated in a region having a depth at which a dopant concentration reaches a peak.

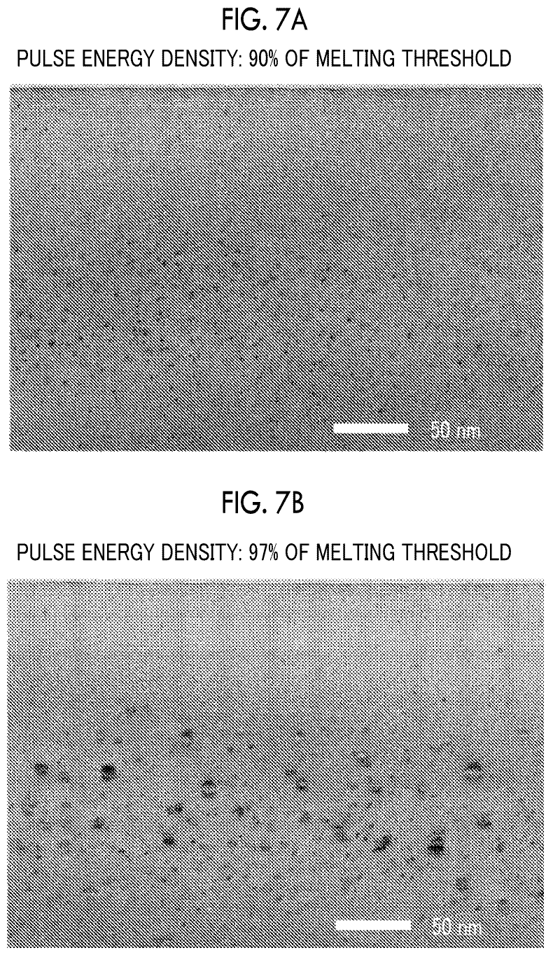

Next, a relationship between the energy density of a laser beam per pulse (hereinafter, referred to as a pulse energy density) and generated defects will be described with reference to FIGS. 7A and 7B.

FIGS. 7A and 7B are cross-section TEM images of a silicon substrate in a case where annealing is performed with pulse energy densities of 90% and 97% of a minimum pulse energy density at which the surface of the silicon substrate is melted due to the incidence of a pulsed laser beam (hereinafter, referred to as a melting threshold), respectively. A sample is a silicon substrate into which boron ions are implanted under a condition in which a concentration reaches a peak at a depth of about 100 nm. A dose of boron is 5×10¹⁴ cm⁻².

It is found that {311} defects are generated in a case where a pulse energy density is set to 90% of the melting threshold (FIG. 7A) and dislocation loops are generated in a case where a pulse energy density is increased up to 97% of the melting threshold (FIG. 7B). In a case where a pulse energy density is adjusted as described above, the types of defects to be generated can be made different. Both of the {311} defects and the dislocation loops can be used as lifetime killers.

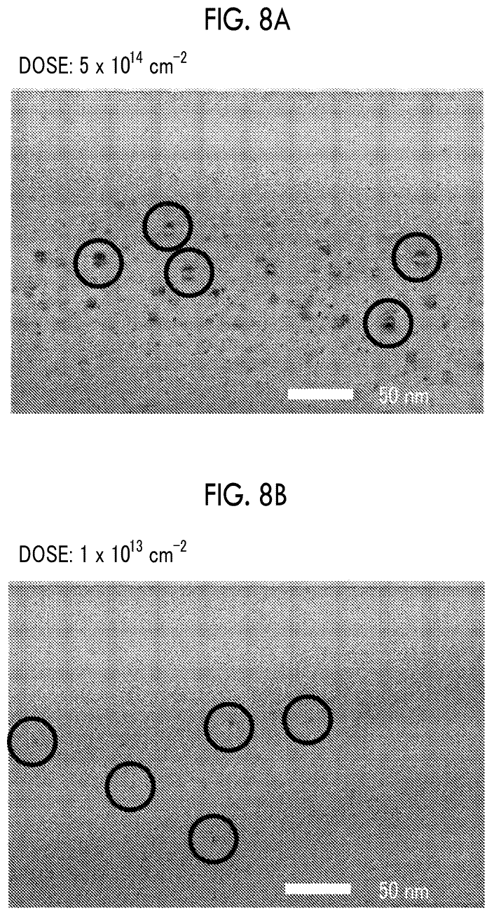

Next, a relationship between a dose and generated defects will be described with reference to FIGS. 8A and 8B.

FIGS. 8A and 8B are cross-section TEM images obtained after the laser annealing of samples that are prepared under conditions in which doses of phosphorus are set to 5×10¹⁴ cm⁻² and 1×10¹³ cm⁻², respectively. A depth at which a phosphorus concentration reaches a peak is about 1 μm and a pulse energy density is set to 97% of the melting threshold.

In a sample for which a dose of phosphorus is 5×10¹⁴ cm⁻² (FIG. 8A), dislocation loops are generated as shown by circles. In a sample for which a dose of phosphorus is 1×10¹³ cm⁻² (FIG. 8B), dislocation loops are not observed and {311} defects extending in a direction perpendicular to the plane of paper are generated as shown by circles. Further, even in both of the samples, an activation rate is 80% or more and a sufficiently high activation rate is achieved.

In a case where doses are different from each other even though a pulse energy density during laser annealing is the same, the types of generated defects may be different from each other. Both of the {311} defects and the dislocation loops can be used as lifetime killers.

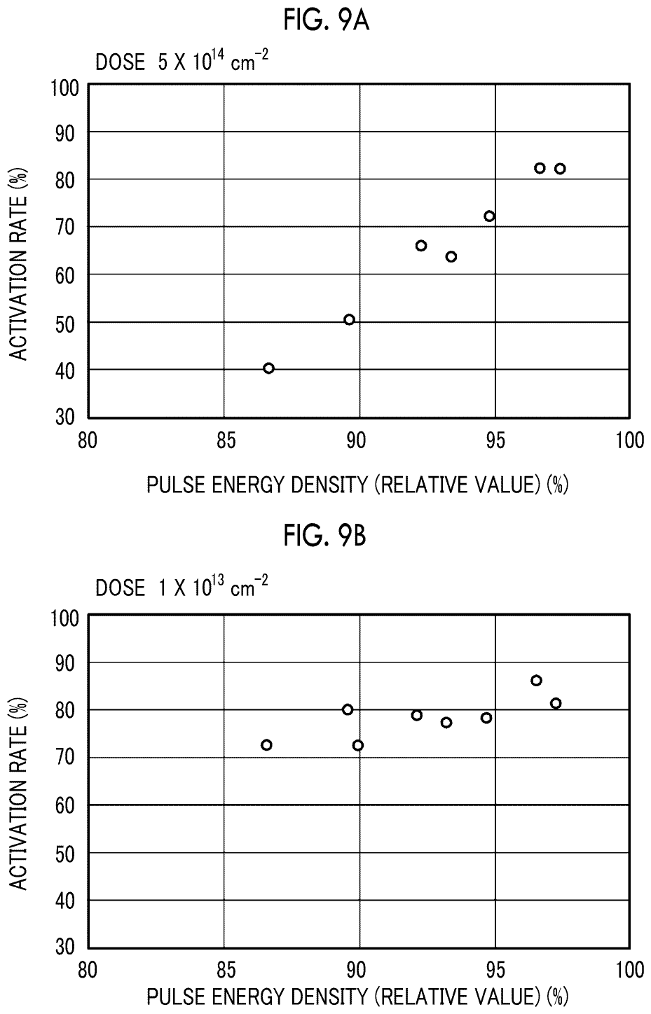

Next, a relationship between a pulse energy density and an activation rate will be described with reference to FIGS. 9A and 9B. FIGS. 9A and 9B are graphs showing a relationship between a pulse energy density and an activation rate. A horizontal axis represents a ratio of a pulse energy density to the melting threshold in the unit “%”, and a vertical axis represents an activation rate in the unit “%”. FIGS. 9A and 9B show activation rates of samples for which doses of boron are set to 5×10¹⁴ cm⁻² and 1×10¹³ cm⁻², respectively.

In a case where a pulse energy density is set to 97% or more of the melting threshold in a sample for which a dose of boron is 5×10¹⁴ cm⁻², an activation rate of 80% or more is achieved. In a case where a pulse energy density is set to 90% or more of the melting threshold in a sample for which a dose of boron is 1×10¹³ cm⁻², an activation rate of 80% or more or an activation rate substantially close to 80% is achieved. Further, in a case where the activation annealing is performed under such a condition, either {311} defects or dislocation loops can be generated. In a case where a dose is smaller, a desired activation rate can be achieved even under a condition in which a pulse energy density is lower than 90% of the melting threshold.

Next, excellent effects of the above-mentioned embodiment will be described.

In the above-mentioned embodiment, {311} defects or dislocation loops generated due to the activation annealing are used as lifetime killers. In the past, light elements, such as proton, have been implanted and annealing has been performed to generate lifetime killers. Since lifetime killers are generated in a step of the activation annealing without the implantation of proton in the above-mentioned embodiment, lifetime killers can be generated without an increase in the number of steps.

In the past, it has been considered that a sufficiently high activation rate cannot be achieved in a case where {311} defects or dislocation loops remain after the activation annealing. Accordingly, post-treatment for eliminating these defects remaining after the activation annealing has been performed. The inventors of the present invention have found through the evaluation experiment described in the above-mentioned embodiment that a sufficiently high activation rate can be achieved even though {311} defects or dislocation loops remain after the activation annealing.

In the above-mentioned embodiment, the pulse width of a pulsed laser beam used for the activation annealing is set to a range of 10 μs to 100 μs. Even though the pulse width is changed, a pulse energy density is made constant in a case where peak power is changed according to a change in pulse width. In a case where a pulse width is shortened and peak power is increased, large laser energy is applied to an extremely shallow region of a silicon substrate in an extremely short time. Accordingly, even though a pulse energy density is low, the surface of the silicon substrate may be melted. That is, the melting threshold of a pulse energy density is changed depending on the pulse width.

A case where the IGBT is manufactured as a power semiconductor device has been described in the above-mentioned embodiment, the activation annealing of the above-mentioned embodiment can also be applied to the manufacture of other power semiconductor devices.

The above-mentioned embodiment is exemplary, and the present invention is not limited to the above-mentioned embodiment. It will be apparent to those skilled in the art that various modifications, improvements, combinations, and the like can be made.

It should be understood that the invention is not limited to the above-described embodiment, but may be modified into various forms on the basis of the spirit of the invention. Additionally, the modifications are included in the scope of the invention.

What is claimed is:

1. A method of manufacturing a semiconductor device, the method comprising:
performing laser annealing on a silicon substrate in which point defects are generated due to ion implantation of a dopant to activate the dopant; and
growing the point defects into {311} defects or dislocation loops and using the {311} defects or the dislocation loops as lifetime killers.

2. The method of manufacturing a semiconductor device according to claim 1,
wherein a wavelength of a laser beam used for the laser annealing is 600 nm or more and 1200 nm or less.

3. The method of manufacturing a semiconductor device according to claim 1,
wherein a laser beam used for the laser annealing is a pulsed laser beam, and
the pulsed laser beam is incident on the silicon substrate under a condition in which a pulse energy density on a surface of the silicon substrate is lower than a melting threshold that is a minimum pulse energy density at which the surface of the silicon substrate is melted due to incidence of the pulsed laser beam.

4. The method of manufacturing a semiconductor device according to claim 3,
wherein the pulsed laser beam is incident on the silicon substrate under a condition in which the pulse energy density on the surface of the silicon substrate is equal to or higher than 97% of the melting threshold.

5. A semiconductor device comprising:
a first layer which is disposed in an outer layer portion of a silicon substrate and into which a first conductive type dopant is implanted;
a second layer that is disposed in a region of the silicon substrate shallower than the first layer and into which a second conductive type dopant is implanted; and
lifetime killers that are formed of {311} defects or dislocation loops formed in at least one of the first layer and the second layer.

6. The semiconductor device according to claim 5,
wherein the lifetime killers are unevenly distributed in a region of the silicon substrate having a depth at which a concentration of at least one of the first conductive type dopant and the second conductive type dopant is highest in a depth direction of the silicon substrate.

7. The semiconductor device according to claim 6,
wherein in a case where a depth of ion implantation is changed, a depth of a region in which the lifetime killers are generated is changed.

8. The semiconductor device according to claim 7,
wherein the lifetime killers are the dislocation loops.

9. The semiconductor device according to claim 5,
wherein the dislocation loops grow by absorbing interstitial silicon atoms released due to decomposition of the {311} defects.

10. The semiconductor device according to claim 9,
wherein each of the dislocation loops is a defect in which silicon atoms are clustered in a shape of a disk.

11. The semiconductor device according to claim 9,
wherein each of the dislocation loops looks like a shape of a ring or a coffee bean in a transmission electron microscope image.

12. The semiconductor device according to claim 5, further comprising:
a collector electrode that is formed on a surface of the second layer.

13. The semiconductor device according to claim 12,
wherein the collector electrode is formed after the dislocation loops are generated due to the {311} defects.
